(19) United States
(12) Patent Application Publication
(10) Pub. No.: US 2009/0263735 A1
(43) Pub. Date: Oct. 22, 2009

(54) EXPOSURE APPARATUS

(75) Inventor: Kazuhiko Mishima, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/427,595

(22) Filed: Apr. 21, 2009

(30) Foreign Application Priority Data
Apr. 22, 2008 (JP) 2008-111093

(51) Int. Cl. G03F 7/20; G03B 27/42; G06F 19/00

(52) U.S. Cl. 430/30; 355/53; 702/85

(57) ABSTRACT

An exposure apparatus includes a plurality of module each of which is configured to expose a pattern of an original onto the substrate using light from a light source, each module including a projection optical system configured to project the pattern of the original onto the substrate and designed to have an identical structure, and a controller configured to control exposures of the plurality of modules using a correction value that is set for each module and configured to correct a scatter of an imaging characteristic of the pattern of the original to be exposure onto the substrate, the controller obtaining the correction value from an inspection result obtained by sequentially mounting an inspection original onto each module.

### BACKGROUND OF THE INVENTION

1. Field of the Invention

The present invention relates to an exposure apparatus.

2. Description of the Related Art

There are conventionally known exposure apparatuses configured to expose a pattern of an original (a mask or a reticle) onto a substrate. The throughput and overlay accuracy are important parameters in the exposure. The focusing accuracy is also important so as to maintain a light intensity and a resolving critical dimension (“CD”) on the substrate.

For an improvement of the throughput, Japanese Patent Laid-Open No. (“JP”) 2007-294583 proposes an exposure apparatus that includes a plurality of exposure units (or modules), each including an illumination apparatus, an original, a projection optical system, and a substrate, and standardizes an original supply part.

In order maintain the overlay accuracy, it is known to expose and develop a test substrate (or a pilot wafer), to inspect the developed substrate, to acquire a correction value used to correct an alignment error, and to set the correction value to the exposure apparatus. The correction value of the alignment error contains a shot arrangement component (such as a magnification, a rotation, an orthogonality, a high order function), and a shot shape component (such as a magnification, a rotation, a skew, a distortion, and a high order function).

JP 2007-294583 premises that a plurality of modules expose different patterns of originals onto substrates (paragraph no. 0002 of JP 2007-29458), but it is conceivable that a plurality of modules expose the same original pattern onto substrates. For example, each module can expose an identical original pattern (first pattern) onto a substrate, and another identical original pattern (second pattern) onto another layer on the substrate. However, when a module that has exposed the first pattern and a module that has exposed the second pattern are different from each other for a certain substrate, the overlay accuracy may degrade between the first pattern and the second pattern. Although this problem may be solved by always matching a substrate with a module that processes that substrate, the management becomes arduous. Hence, in order to expose one substrate with a plurality of modules, it is necessary to reduce a scatter of imaging characteristics among the modules. The factor that degrades the overlay accuracy contains an aberration of a projection optical system, a shape distortion of an original, and errors that occur in an exposure and a variation with time (such as aberrational changes of the projection optical system caused by the heat as a result of absorptions of the exposure light, deformations of the original and/or the original stage, or a focusing error).

### SUMMARY OF THE INVENTION

The present invention provides an exposure apparatus having a high throughput and high overlay accuracy.

An exposure apparatus according to one aspect of the present invention includes a plurality of module each of which is configured to expose a pattern of an original onto a substrate using light from a light source, each module including a projection optical system configured to project the pattern of the original onto the substrate and designed to have an identical structure, and a controller configured to control exposures of the plurality of modules using a correction value that is set for each module and configured to correct a scatter of an imaging characteristic of the pattern of the original to be exposure onto the substrate, the controller obtaining the correction value from an inspection result obtained by sequentially mounting an inspection original onto each module.

Further aspects and features of the present invention will become apparent from the following description of exemplary embodiments (with reference to the attached drawings).

### BRIEF DESCRIPTION OF THE DRAWINGS

FIG. 1 is a block diagram of a multi-module exposure apparatus according to one embodiment of the present invention.

FIG. 2 is an optical-path diagram for explaining a baseline measurement in each module in the multi-module exposure apparatus shown in FIG. 1.

FIGS. 3A-3C are sectional and plane views showing a structure of a reference mark shown in FIG. 2.

FIG. 4 is a graph showing a light quantity change obtained from the reference mark.

FIG. 5 is a block diagram for explaining a wafer transportation system shown in FIG. 1.

FIG. 6 is a block diagram for explaining a reticle transportation system shown in FIG. 1.

FIG. 7 is a schematic, partially transparent perspective view of a reticle holder configured to hold a reticle shown in FIG. 1.

FIGS. 8A and 8B are perspective and plane views showing shifts of patterned surfaces of the reticle shown in FIG. 7.

FIG. 9 is a graph showing a positional error to an image point in a projection optical system shown in FIG. 1 which occurs due to the distortion.

FIG. 10 is a graph showing a curvature of field to an image point when there is a focusing error.

FIG. 11 is a plane view of an inspection reticle used to measure a shape of the reticle shown in FIG. 1.

FIG. 12 is a block diagram of an overlay inspection apparatus.

FIG. 13 is a plane view of a wafer shown in FIG. 1.

FIG. 14 is a flowchart for explaining an acquisition method of a correction value for an image error of the exposure apparatus shown in FIG. 1.

FIG. 15 is a flowchart for explaining an acquisition method of a correction value for an image error of the exposure apparatus shown in FIG. 1.

FIG. 16 is a flowchart for explaining an acquisition method of a correction value for an image error of the exposure apparatus shown in FIG. 1.

### DESCRIPTION OF THE EMBODIMENTS

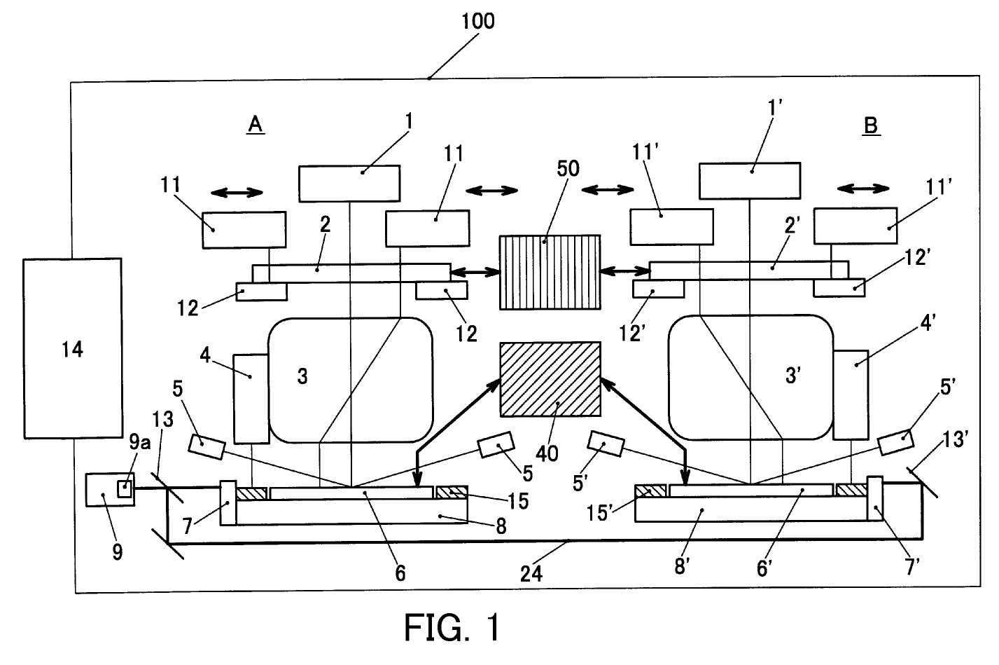

Referring now to the accompanying drawings, a description will be given of an exposure apparatus according to one aspect of the present invention. The exposure apparatus 100 is a multi-module exposure apparatus that includes, as shown in FIG. 1, a plurality of modules A and B. Each module exposes a pattern of an original onto a substrate using light from a light source. In this embodiment, the A module and the B module are designed to have an identical structure, and corresponding elements are distinguished from each other by a prime appended to a reference numeral. In the following description, unless otherwise specified, a reference numeral without a prime generalizes the same reference numeral with a prime.

The exposure apparatus 100 may house in one housing a plurality of modules each including an illumination apparatus, an original, a projection optical system, a position detection apparatus, and a substrate, or may house each module in a separate housing. By accommodating a plurality of modules in a single housing, one controller can control the exposure environment, and it is unnecessary to take a substrate to the outside of the housing in moving the substrate among the modules.

Each module includes an illumination apparatus 1, a projection optical system 3, a wafer driving system, a focusing system, a transportation system, an alignment system, and a controller 14, and exposes a pattern of a reticle 2 onto a wafer 6 in a step-and-scan manner. The present invention is applicable to an exposure apparatus of a step-and-repeat manner.

The illumination apparatus 1 illuminates the reticle 2, and includes a light source and an illumination optical system. The light source can use a laser or a mercury lamp. The illumination optical system is an optical system configured to uniformly illuminate the reticle 2.

The reticle 2 has a circuit pattern (or image), is supported and driven by a reticle stage (omitted in FIG. 1) via a reticle holder, which will be described later. The position of the reticle stage (not shown) is always measured by an interferometer 9. The diffracted light emitted from the reticle 2 is projected onto the wafer 6 via the projection optical system 3. In order to expose the wafers 6, 6′ with identical patterns, the reticles 2, 2′ of this embodiment have identically designed patterns. The reticle 2 and the wafer 6 are arranged in an optically conjugate relationship. Each module of the exposure apparatus 100 serves as a scanner, and transfers the reticle pattern onto the wafer 6 by synchronously scanning the reticle 2 and the wafer 6 at a velocity ratio corresponding to a reduction ratio.

The projection optical system 3 projects the light that reflects the reticle pattern onto the wafer 6. The projection optical system 3 may use any one of a dioptric optical system, a catadioptric optical system, and a catoptric optical system. An immersion exposure may be implemented by immersing in a liquid a final optical element of the projection optical system 3 closest to the wafer 6.

The wafer 6 is a liquid crystal substrate in another embodiment, and represents an object to be exposed. A photoresist is applied onto a surface of the wafer 6. A pattern is exposed onto the wafer 6, and an area corresponding to one exposure is referred to as a shot. The wafer 6 has alignment marks used for an alignment between the reticle 2 and each shot on the wafer 6, and an off-axis (“OA”) scope 4 measures the alignment marks. Thereafter, a statistic process, such as a least squares approximation, is performed so as to calculate a positional shift of the wafer 6, a wafer magnification, an orthogonality, a reduction ratio of the shot arrangement grating, etc. from an overall tendency of the detection result from which a queerly deviate detection result is removed. The alignment marks are formed on scribe lines among the shots, or between adjacent shots.

The wafer driving system drives the wafer 6, and includes a wafer stage 8 and an interferometer 9. The wafer stage 8 utilizes a linear motor, can move in the XYZ and their rotating directions, and supports and drives the wafer 6 via a chuck (not shown). A position of the wafer stage 8 is always measured with the interferometer 9 that refers to a bar mirror 7. A reference mark 15 is formed on the wafer stage 8. In exposing the reticle pattern onto the wafer 6, the wafer stage 8 and the reticle stage are driven based on a calculation result of the global alignment system.

In general, a wavelength of the interferometer changes depending upon an environment factor (such as an atmospheric pressure, a temperature, and a humidity), and a light source fluctuation of the interferometer, and causes fluctuations of the measurement value. In the multi-module exposure apparatus, when the interferometers for the wafer stages in the respective modules independently change, the alignment accuracy lowers. In addition, when the interferometers for the reticle stages independently change, a positional relationship between the reticle and the wafer may destroy. Accordingly, all the interferometers in the exposure apparatus 100 share the light source. More specifically, the light from a light source 9a for the position detection built in the interferometer 9 shown in FIG. 1 is used, via the mirrors 13, for the interferometer for the wafer stage 8 and for the interferometer for the reticle stage in the A module and the B module. Instead of this mirror 13, an optical fiber may be used.

The focusing system detects a position of the wafer surface in the optical-axis direction in order to place the wafer 6 at a focus position of an image which the projection optical system 3 forms. The focusing system includes a focus position detector 5. More specifically, the focus position detector 5 projects obliquely incident light that has passed a slit pattern onto a wafer surface, photographs the slit pattern reflected on the wafer surface by using an image sensor, such as a CCD, and measures a focusing position of the wafer 6 from a position of the slit image obtained by the image sensor.

The alignment system includes a Fine Reticle Alignment (“FRA”) system, a Through The Reticle (“TTR”) system, a Through The Lens (“TTL”) system, and the OA system.

The FRA system is a system that observes a reticle reference mark formed on the reticle 2 and a reticle reference mark 12 formed on the reticle stage using the FRA scope (position detection apparatus) 11, and is used to align them with each other. These reticle reference marks serve as alignment marks, illuminated by the illumination apparatus 1, and simultaneously observed by the FRA scope 11. For example, the reticle reference mark (not shown) may be formed as one first mark element on a surface of the reticle 2 on the side of the projection optical system 3, and the reticle reference mark 12 is provided with a pair of second mark elements. The FRA scope 11 is used for the alignment so that the first mark element can be located between the second mark elements.

The TTR system is a system that observes the reticle reference mark formed on the reticle 2 and a stage reference mark 15 formed on the wafer stage 8 via the projection optical system 3 with the FRA scope 11, and aligns them with each other. The reticle reference mark is also referred to as a baseline (“BL”) mark or a calibration mark. The BL mark corresponds to the center of reticle pattern. These reference marks serve as alignment marks, illuminated by the illumination apparatus 1, and simultaneously observed by the FRA scope 11. The FRA scope 11 is located movably above the reticle 2, can observe both the reticle 2 and the wafer 6 at a plurality of image points of the projection optical system 3 through the reticle 2 and the projection optical system 3, and can detect a positional shift between the reticle 2 and the wafer 6. A scope of the FRA system may be separate from a scope of the TTR system. For example, the BL mark may be formed as one third mark element on a surface of the reticle 2 on the side of the projection optical system 3, and the stage reference mark 15 is provided with one fourth mark element. The FRA scope 11 is used for the alignment so that the third mark element can overlap the fourth mark element.

The TTL system measures the stage reference mark 15 via the projection optical system 3 using a scope (not shown) and the non-exposure light. For example, the non-exposure light is guided from a He—Ne laser (having an oscillation wavelength of 633 nm) to an optical system via a fiber, and Koehler-illuminate the stage reference mark 15 on the wafer 6 via the projection optical system 3. The reflected light from the stage reference mark 15 forms an image on an image sensor in the optical system from the projection optical system 3 in a direction reverse to the incident light. The image is photoelectrically converted in the image sensor, and a resultant video signal undergoes a variety of image processes, and a position of the alignment mark is positioned.

The OA system detects an alignment mark of the wafer 6 without interposing the projection optical system 3 using the OA scope 4. The optical axis of the OA scope 4 is parallel to that of the projection optical system 3. The OA scope 4 is a position detection apparatus having an internal index mark (not shown) arranged conjugate with the surface of the reference mark 15. Arrangement information of the shots formed on the wafer 6 is obtained from a measurement result of the interferometer 9 and an alignment mark measurement result by the OA scope 4.

In advance to this, it is necessary to calculate a baseline that is an interval between the measurement center of the OA scope 4 and the projected image center (exposure center) of the reticle pattern. The OA scope 4 detects a shift amount from the measurement center of the alignment mark in the shot on the wafer 6, and the wafer 6 is moved from the OA scope by a distance corresponding to this shift amount added to the baseline. Then, the center of the shot area is aligned with the exposure center. Since the baseline varies with time, periodical measurements are needed.

Shot shape information is acquired by measuring alignment marks formed at a plurality of points in each shot. More precise positioning is available by correcting and exposing the shot shape based on the shot shape information.

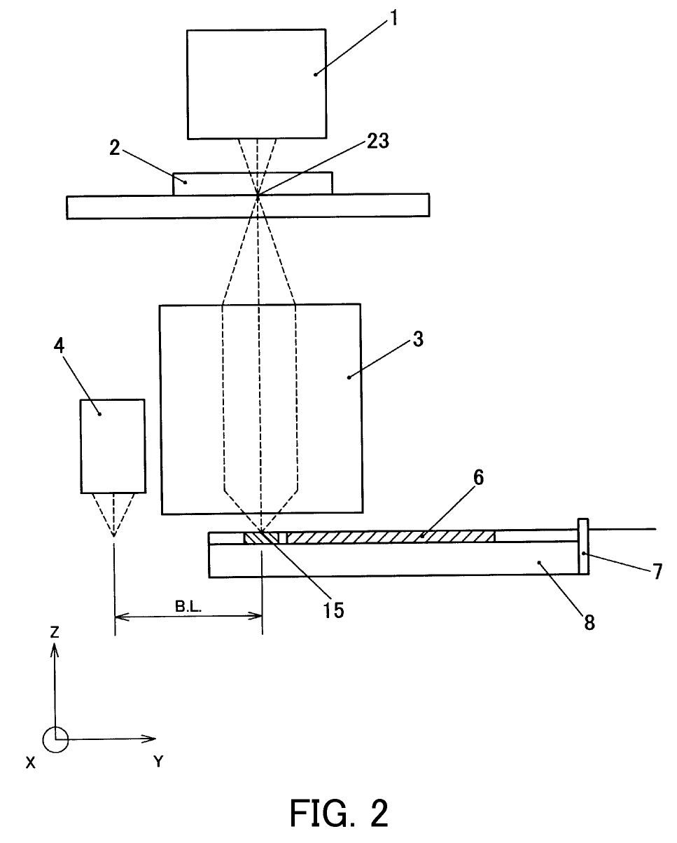

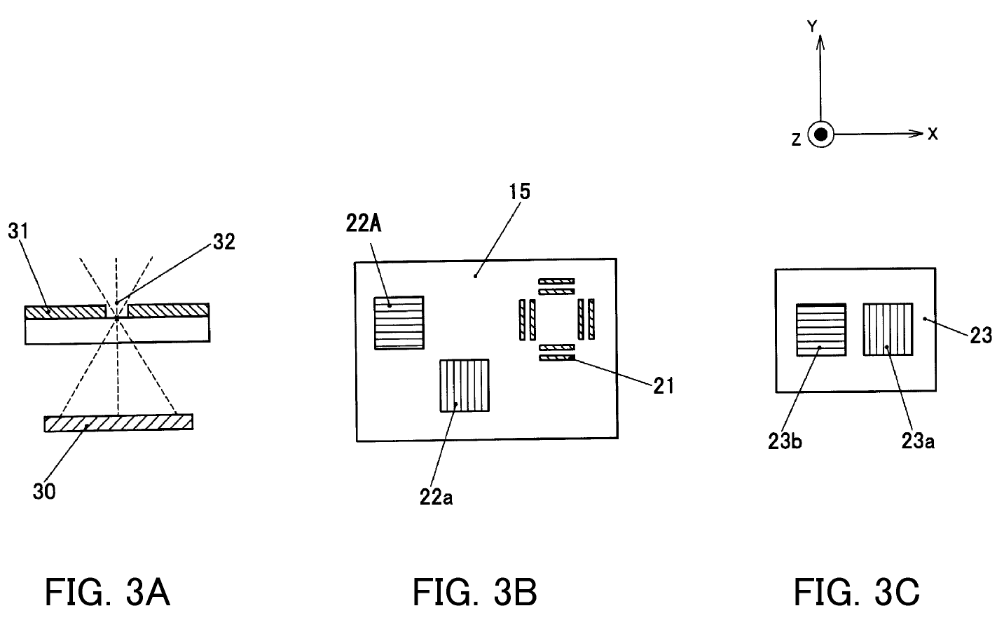

Referring now to FIGS. 2 and 3C, a baseline measurement method will be described. FIG. 2 shows a BL mark 23 formed on the reticle 2. FIG. 3C is a plane view of the BL mark 23. The BL mark 23 includes a mark element 23a for X-direction measurements and a mark element 23b for Y-direction measurements. The mark 23a has a longitudinal direction in the X direction, and possesses a repetitive pattern of openings and light shields. The mark element 23b is formed as a mark having openings extending in a direction orthogonal to those of the mark element 23a. The BL mark of this embodiment uses the mark elements 23a and 23b along the XY directions when the XY coordinate is defined as shown in FIG. 3C, but the orientation of the mark element is not limited to this embodiment. For example, the BL mark 23 may have a measurement mark that inclines to the X axis or Y axis by 45° or 135°. When the mark elements 23a and 23b are illuminated by the illumination apparatus 1, the projection optical system 3 forms patterned images of the transmission parts (openings) of the mark elements 23a and 23b, at the best focus position on the wafer side.

Next, as shown in FIGS. 3A and 3B, the reference mark 15 includes a position measurement mark 21 which the OA scope 4 can detect, and mark elements 22a and 22A as large as the projected images of mark elements 23a and 23b. FIG. 3A is a sectional view of the reference mark 15, and FIG. 3B is a plane view of the reference mark 15. The mark elements 22a and 22A are formed by light shields 31 having a light shielding characteristic to the exposure light and a plurality of openings 32. FIG. 3A shows only one opening for convenience. The light that has transmitted the opening 32 reaches a photoelectric conversion element 30 under the reference mark 15. The photoelectric conversion element 30 can measure the intensity of the light that has transmitted the opening 32. The position measurement mark 21 is detected by the OA scope 4.

Next follows a description of a baseline calculation method using the reference mark 15. Initially, the mark elements 23a and 23b are moved to positions at which the exposure light passes through the projection optical system 3. A description will be given of the mark element 23a by an example. This description is applicable to the mark element 23b. The moved mark element 23a is illuminated by the illumination apparatus 1. The projection optical system 3 forms an image of the light that has passed the transmission part of the mark element 23a, as a mark pattern image at an imaging position in the wafer space. By driving the wafer stage 8, the mark element 22a having the same shape as the mark pattern image is arranged at a corresponding position. This state is a state in which the reference mark 15 is arranged on the imaging surface (or the best focus surface) of the mark element 23a. An output value of the photoelectric conversion element 30 is monitored while the mark element 22a is driven in the X direction.

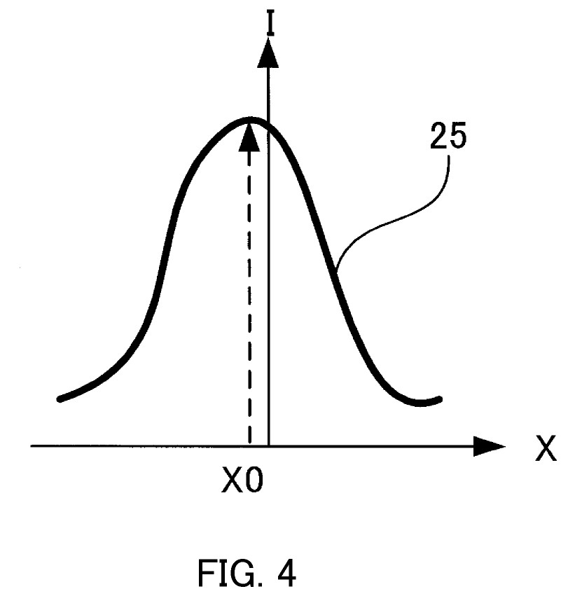

FIG. 4 is a graph that plots the position of the mark element 22a in the X direction and the output value of the photoelectric conversion element 30. In FIG. 4, an abscissa axis denotes a position of the mark element 22a in the X direction, and an ordinate axis denotes an output value I of the photoelectric conversion element 30. When a positional relationship changes between the mark element 23a and the mark element 22a, the photoelectric conversion element 30 changes the output value. In this change curve 25, a maximum intensity is available at a position X0 at which the mark element 23a overlaps the mark element 22a. A position of the projected image of the mark element 23a on the side of the wafer space due to the projection optical system 3 can be calculated by calculating the position X0. The position X0 can be stably and precisely acquired by calculating a peak position by performing a gravity calculation or a function approximation for a predetermined area in the change curve 25.

A position X1 of the wafer stage 8 when the mark elements 22a and 22A overlap the mark elements 23a and 23b in the Z direction is obtained from the interferometer 9. A position X2 of the wafer stage 8 when the index mark in the OA scope 4 overlaps the position measurement mark 21 in the Z direction is obtained from the interferometer 9. Thereby, the baseline can be calculated by X1−X2.

While the above description assumes that the reference mark 15 of the projected image is located on the best focus surface, the reference mark 15 may not be located on the best focus surface in the actual exposure apparatus. In that case, the best focus surface can be detected and the reference mark 15 can be arranged there by monitoring an output value of the photoelectric conversion element 30 while the reference mark 15 is driven in the Z direction (optical-axis direction). In that case, when it is considered that the abscissa axis denotes a focusing position, and the ordinate axis denotes an output value I in FIG. 4, the best focus surface can be calculated by a similar process.

When the reference mark 15 shifts not only in the XY directions but also in the Z direction, a measurement in one of the directions is performed to secure predetermined accuracy, and then a positional detection in another direction follows. An optimal position can be finally calculated by repeating the above procedures alternately. For example, where there is a shift in the Z direction, an X-direction measurement with low accuracy is performed through X-direction driving to calculate a rough position in the X direction. Thereafter, it is driven in the Z direction at that position to calculate the best focus surface. Next, X direction driving and measurement again follow to precisely acquire the optimal position in the X direction. Usually, one set of such alternate measurements can guarantee a high precision of the measurement. While the above illustration starts with the X-direction measurement, starting with a Z-direction measurement can finally provide precise measurement.

When the exposure apparatus and the wafer 6 are not in the ideal states, the exposed wafer 6 possesses a slight positioning error. Usually, each component of a positioning error is analyzed and fed back to the exposure apparatus for calibrations to exposures of the next and subsequent wafers 6. The alignment error component contains, in the shot arrangement state, a primary component (such as a shift component of all shots, a magnification of each shot arrangement, a rotation, and an orthogonality), and a high order component that occurs in an arch shape, and these are calculated as individual components in the X and Y directions. In addition, in the shot shape, there are a variety of shape components, such as a magnification, a rotation, a rhombic shape, and a trapezoid shape of a shot. In particular, in the scanner, the rhombic component of the shot is likely to occur. A shot arrangement component and a shot shape component are fed back to the exposure apparatus and corrected.

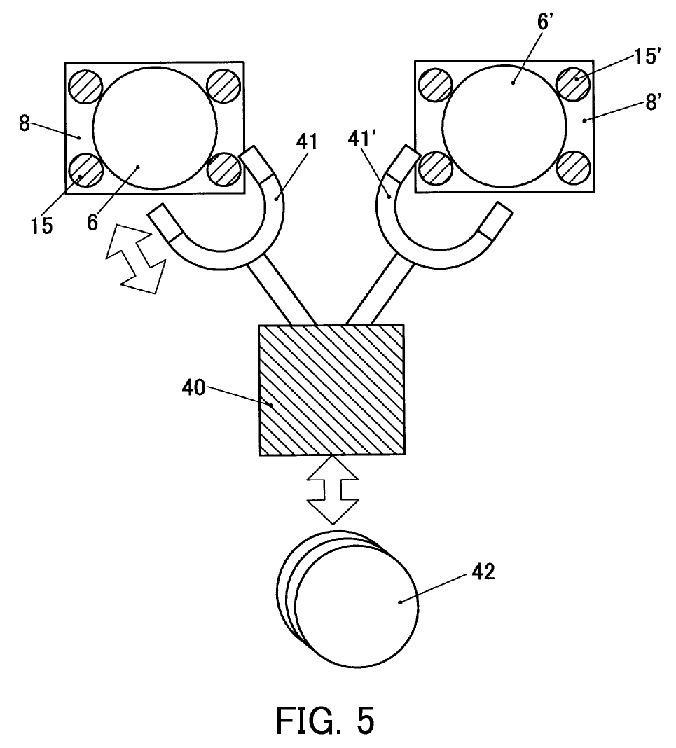

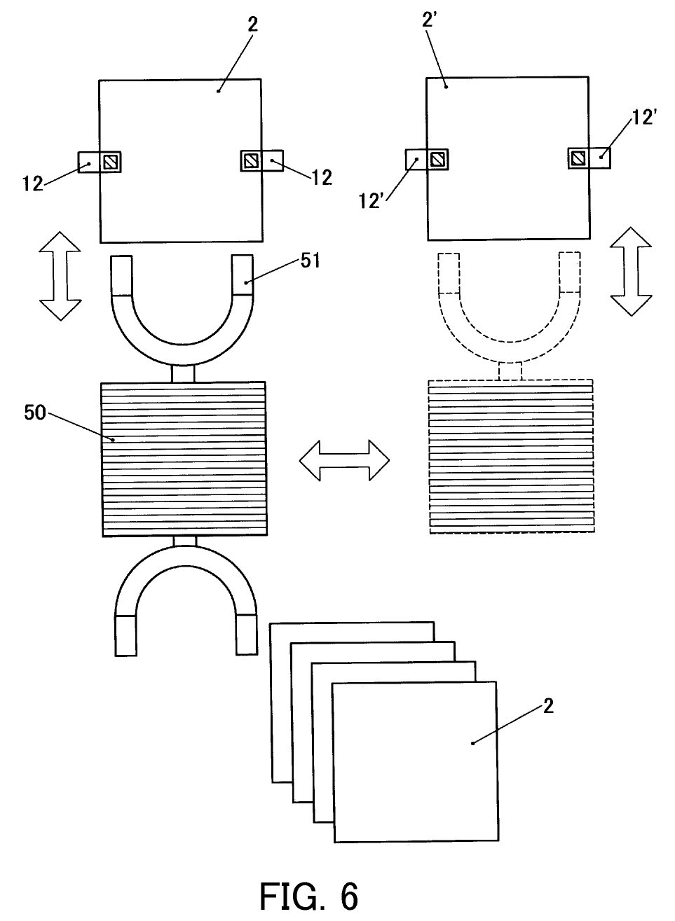

The transportation system includes one wafer transportation system 40 configured to transport the wafer 6 to the wafer stage 8, and one reticle transportation system 50 configured to transport the reticle to the reticle stage. FIG. 5 is a block diagram of the wafer transportation system 40. FIG. 6 is a block diagram of the reticle transportation system 50.

As shown in FIG. 5, a plurality of pre-exposure wafers 42 are supplied to the wafer transportation system 40 from a coater configured to apply the photoresist. The supplied wafer 42 is sequentially transported to the wafer stage 8 in each module by a wafer hand 41. The exposed wafer 6 is recovered by the wafer hand 41, and transported to a developer (not shown) configured to develop the photoresist. The wafer transportation system 40 can transport the wafer between both modules.

As shown in FIG. 6, in accordance with an instruction by the controller 14, the reticle 2 is transported to the reticle stage at a proper timing from a stocker that stores a plurality of reticles 2. It is effective to arrange the reticle 2 on the reticle stage via a particle inspector (not shown) configured to inspect a particle on the reticle 2. In FIG. 6, one reticle transportation system 50 can drive the reticle between both modules and the reticle 2 is sequentially mounted on each module, but the number of reticle transportation systems 50 is not limited. As described above, in this embodiment, the number of reticles 2 having the identically designed pattern corresponds to the number of modules. After the exposure ends, the reticle 2 is recovered from the reticle stage of each module by the reticle transportation system 50 in the reverse procedures.

The controller 14 integrally controls exposure actions of a plurality of modules in the exposure apparatus 100 by one recipe that defines a processing condition of the wafer 6. The recipe is incorporated with a correction value used to correct a scatter of imaging characteristics among module. The controller 14 has a memory (not shown) configured to store the recipe and other information necessary for the controls. Thus, the controller 14 controls exposures by the plurality of modules using a correction value that is set to each module and configured to correct a scatter of imaging characteristics of the pattern of the original to be exposure onto the substrate. The correction value contains a correction value used to correct an imaging error (such as a distortion) in a direction perpendicular to the optical axis of the projection optical system 3, and a correction value used to correct an imaging error (such as a focusing error) in an optical-axis direction of the projection optical system 3.

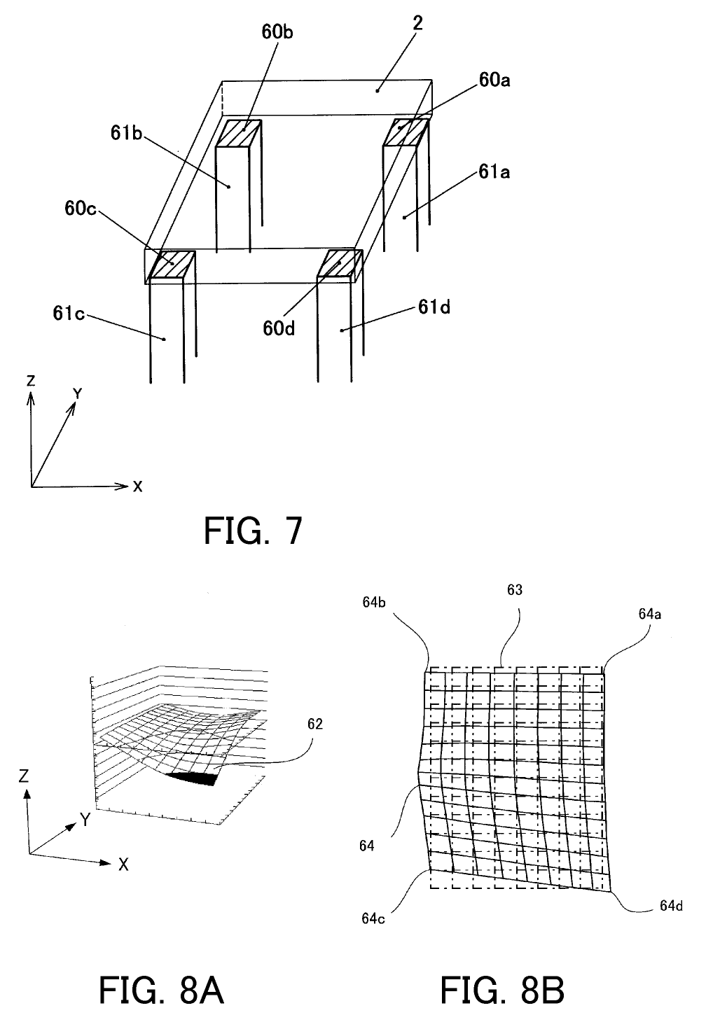

FIG. 7 is a schematic, partially transparent perspective view of four reticle holders 61a to 61d configured to hold the reticle 2 by vacuum-absorbing the reticle 2 on attraction surfaces 60a to 60d. The shape of the reticle holder and the number of reticle holders are not limited to this embodiment, and the reticle holder may hold the bottom surface of the reticle 2 over its circumference. The attraction surfaces 60a to 60d are designed and processed to have the same height, but their actual heights are different due to the processing errors.

FIG. 8A is a perspective view showing a three-dimensional shape of the patterned surface 62 of the reticle 2, where the attraction surface 60d is lower than the other attraction surfaces 60a to 60c. Thus, when the attraction surface 60d is low, the reticle 2 is distorted on its entire surface. The distortion occurs in the height direction (Z direction) and causes a focusing error, and occurs errors in the longitudinal and lateral direction (X and Y directions), causing an overlay error. FIG. 8B is a simulation result of the error in the longitudinal and lateral directions where the attraction surface 60d is lower than the attraction surfaces 60a to 60c. In FIG. 8B, an alternate long and short dash line 63 indicates an ideal shape of the patterned surface of the reticle 2, and a solid line 64 indicates a deformed shape (where 64a to 64d denote vertex points). A deformation is significant at the vertex point 64d, because it is drawn to the lower side. The shape changes as the temperature changes. For example, when the patterned surface of the reticle 2 absorbs the exposure light and its temperature rises, the shape of the patterned surface changes, causing an overlay error and a focusing error.

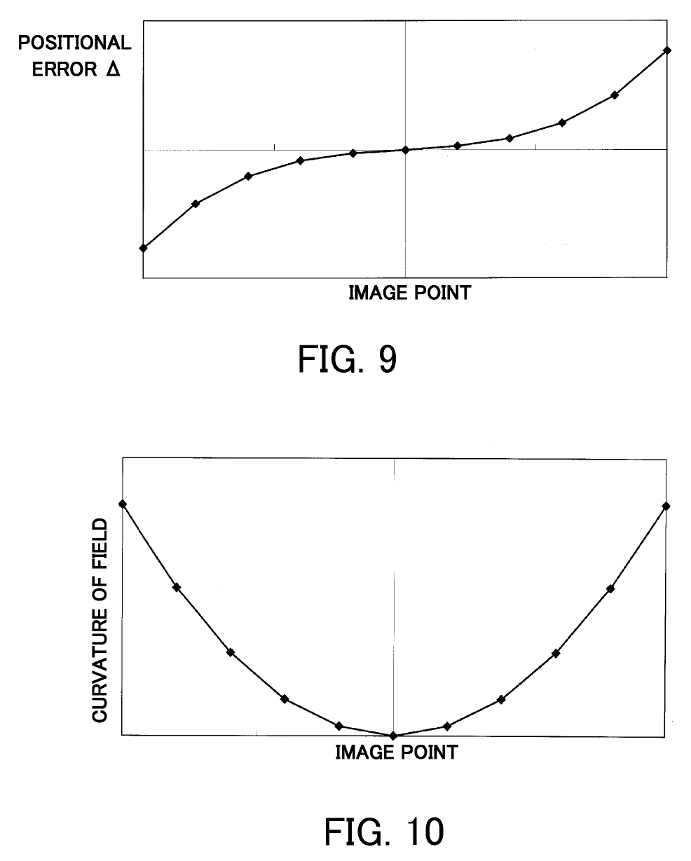

FIG. 9 is a graph showing a positional error A relative to an image point in the projection optical system 3, which occurs due to the distortion. While the projection optical system 3 thus usually possesses a positional error of a tertiary component that depends upon an image point, it further possesses a decentering distortion having a more complex shape which occurs due to decentering of the optical axis. Moreover, a more complicated error may occur due to an optical element, such as a lens and a mirror, of the projection optical system 3. The shape error results from in the manufacture error in the projection optical system 3. In the exposure apparatus 100, a shape error of each projection optical system 3 is highly likely to differ. The shape also changes as the temperature changes. For example, when the projection optical system 3 absorbs the exposure light and its temperature rises, the shape of each optical element changes and the imaging characteristic degrades. In that case, a shape change amount differs according to a difference of a characteristic (such as a transmittance and a reflective index) of each optical element. Therefore, it is necessary to restrain a difference of a thermal change among the modules. Moreover, focusing errors (FIG. 10) differ among the modules in addition to the lateral shifts (distortions), and there is a difference of a thermal change among modules.

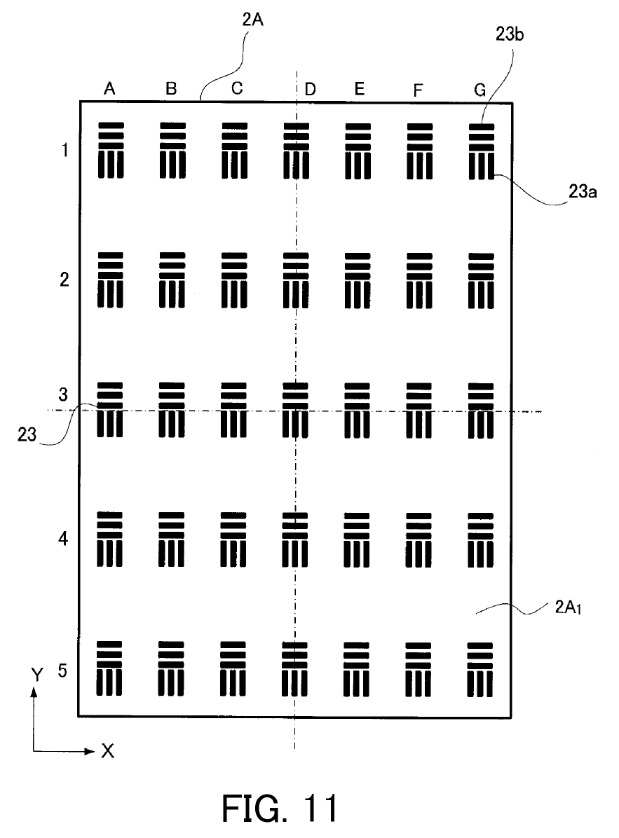

A description will be given of an error measurement method. FIG. 11 is a plane view of an inspection reticle (inspection original) 2A dedicated for a measurement of the shape of the reticle 2. The inspection reticle 2A has a plurality of calibration marks 23 as measurement marks in an exposure area 2A₁, and has the same external shape as the reticle 2 (in size, thickness, and shape except the pattern is the calibration mark 23). A plurality of calibration marks 23 are arranged at a pitch determined by the first to fifth columns that align with the lateral direction (X direction) and “A” row to “G row” that align with the longitudinal direction. The smaller the mark pitch is, the higher the measurement accuracy becomes, but five or more points are sufficient in one direction. A measurement method of the calibration mark 23 has been discussed above.

A correction value of an imaging error of the exposure area 2A₁, such as a distortion and a focusing error, can be obtained by mounting an inspection reticle 2A onto each module.

Instead of measuring the calibration mark 23 with the FRA scope 11 of the TTR system, the correction value of the distortion or the focusing error may be obtained by actually exposing the wafer 6 and inspecting the exposure result with the overlay inspection apparatus. The OA scope 4 may be used instead of the overlay inspection apparatus. In that case, s fast pattern is exposed at both modules using the same wafer.

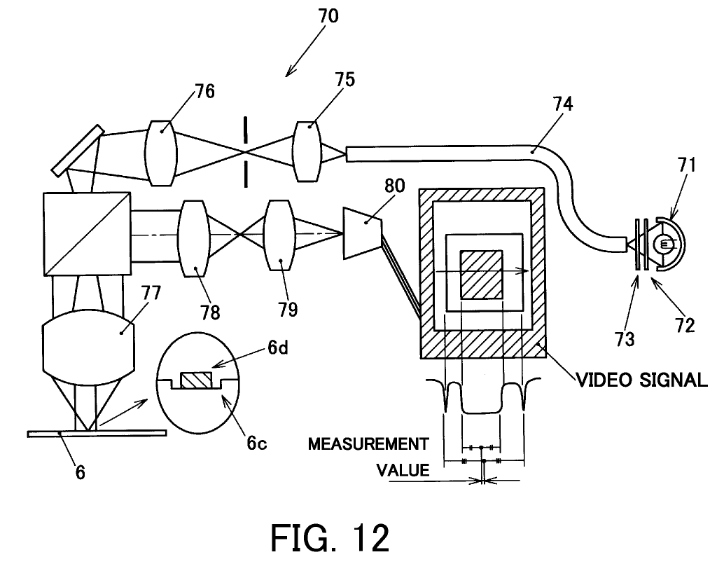

FIG. 12 is a block diagram of an overlay inspection apparatus 70. The overlay inspection apparatus 70 is an apparatus configured to measure an alignment and a distortion of the exposure apparatus, and measures an inter-mark positional relationship among two overlay marks 6c and 6d separately formed as shown in FIG. 12. The overlay inspection apparatus 70 uses a halogen lamp for a light source 71, and selects a proper wavelength band via optical filters 72 and 73. Next, the illumination light is guided to optical systems 75 to 77 via an optical fiber 74, and Koehler-illuminates the overlay marks 6c and 6d on the wafer 6. The light reflected from the wafer 6 is guided to an image sensor 80, such as a CCD camera, through optical systems 77 to 79, and forms an image. A video signal that is generated by photoelectrically converting the image undergoes a variety of image processes, and a positional relationship between the two overlay marks 6c and 6d is detected.

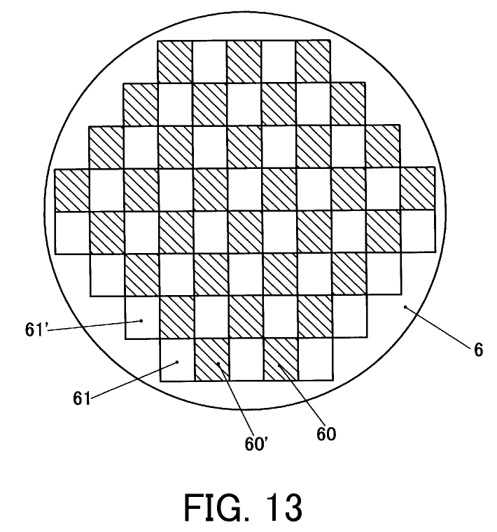

In exposing a fast pattern as a primary coat on the same wafer at both modules, the A and B modules expose different areas on one wafer. FIG. 13 is a plane view of the wafer 6 in that case. Shots which the A module exposes are beveled areas 60 (60′) in FIG. 13, which will be referred to as “A areas.” Shot which the B module exposes are white area 61 (61′), which will be referred to as “B areas.” An arrangement of the A areas and the B areas not limited to a checkerboard arrangement.

A detection result by the FRA scope 11 using the inspection reticle 2A (or a detection result of an exposure result by the overlay inspection apparatus 70) contains a shape change of the inspection reticle 2A and an aberration of the projection optical system 3. Therefore, this information is stored, and an error is corrected or cancelled in the actual exposure time. These areas are true of the errors in the longitudinal and lateral directions (XY) and the focus direction (Z).

In a scanner, respective components, such as a rotational component, an inclination component in the scanning direction, and a magnification component in the scanning direction shown in FIG. 8B are separated, and a correction value can be stored and reflected in the exposure time. On the other hand, the reticle stage is not scanned in the stepper, and thus there is an uncorrectable component. In that case, the aberration of the projection optical system 3 may be corrected so that an error can be averaged for the entire exposure area 2A₁ or an area that requires the precision. In any event, the inspection reticle 2A enables a deformation of the inspection reticle 2A, an aberration of the projection optical system 3, and an error of the reticle stage to be simultaneously measured.

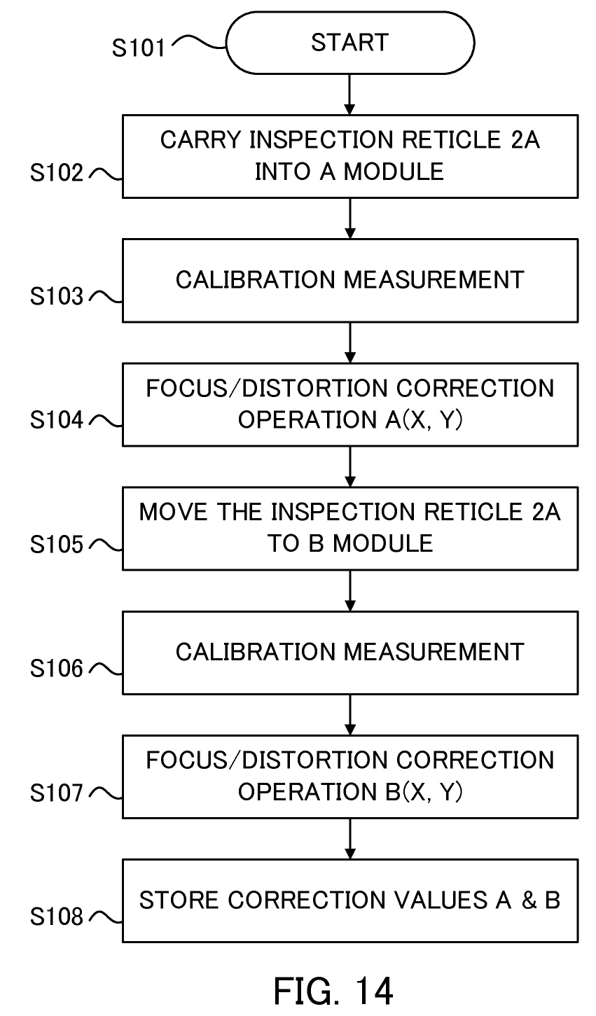

Referring now to FIG. 14, a description will be given of an acquisition method of a correction value to an imaging error of the exposure apparatus 100 mounted with the inspection reticle 2A. The imaging error to be corrected in FIG. 14 is mainly a tool induced shift (“TIS”) caused by the apparatus.

When a measurement starts (S101), the inspection reticle 2A is carried in and mounted onto the A module (S102). Next, the BL mark 23 of the inspection reticle 2A and the reference mark 15 of the wafer stage 8 are simultaneously observed by the FRA scope 11, and a positional shift between them or a positional shift between the inspection reticle 2A and the wafer 6) is detected (S103). This detection will be sometimes referred to as a “calibration measurement” hereinafter. While this embodiment obtains a correction value based on a detection result of the BL mark 23 by the FRA scope 11, the correction value may be obtained by exposing the wafer and by measuring the exposure result with the overlay inspection apparatus. The OA scope 4 may be used instead of the overlay inspection apparatus.

Turning back to FIG. 14, a correction value (A(X, Y)) used to correct a focusing error or distortion is calculated from a calibration result (S104). The correction value is calculated as a value for a position (X, Y). A function conversion process may be provided using a calculated value, or a correction value at each measured point and interpolated values among these points may be stored in the exposure apparatus. The actual calibration measurement provides a measurement result of marks spaced by the pitch, and it is necessary to predict or interpolate the unmeasured interval. For example, since a magnification error is expressed by a primary component of an image point and a distortion is expressed by a tertiary function of an image point, the aberration can be calculated by a tertiary function fitting (least squares method). The obtained correction value contains a deformation component of the inspection reticle 2A, an aberration component of the projection optical system 3, and a driving error of the reticle stage.

When the correction value of the alignment error is calculated in the A module, the inspection reticle 2A is carried in and mounted onto the B module (S105), and a calibration measurement is performed similar to the A module (S106). A correction value (B(X, Y) of the B module is calculated from the obtained measured result (S107). When the exposure apparatus is ideal, A(X, Y)=B(X, Y) (=0) is met, but A(X, Y) is not equal to B(X, Y) in the actual exposure apparatus and a scatter of errors among the modules needs to be corrected. The controller 14 stores the correction values A(X, Y) and B(X, Y) in each module (S108). The controller 14 controls exposure actions of the A and B modules using the stored correction values at the exposure time.

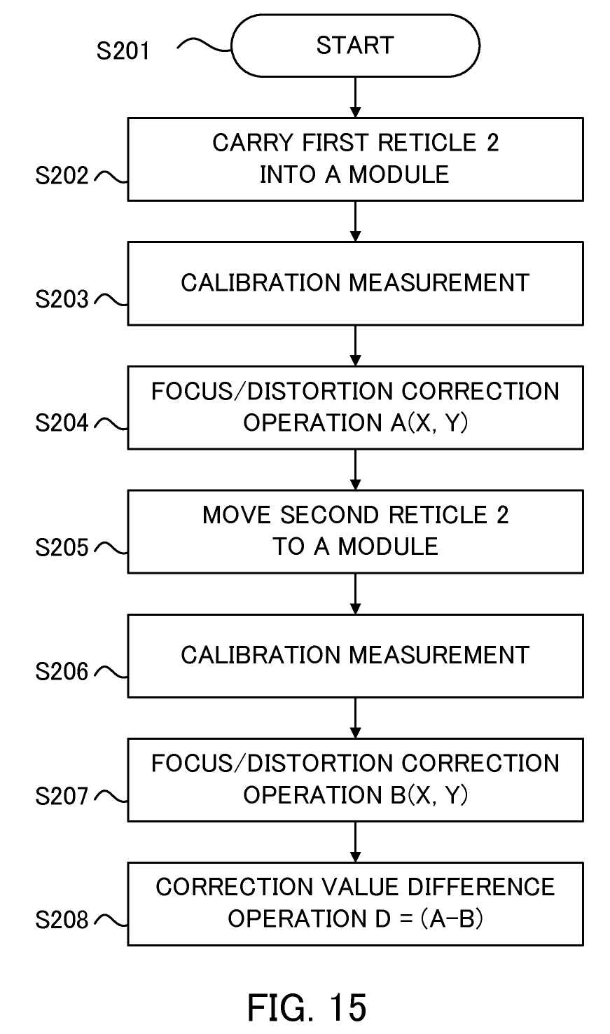

Referring now to FIG. 15, a description will be given of an error correction method by mounting first and second reticles 2 having identically designed, actual patterns onto both modules in the exposure apparatus 100. The correctible imaging error in FIG. 15 is a scatter of shape distortions among the reticles 2.

When a measurement starts (S201), the first reticle (first original) 2 is carried in and mounted onto the A module (first module) (S202), and a calibration measurement is performed as described above with reference to FIG. 14 (S203). A correction value (A(A, Y) of an alignment error is calculated from the obtained measurement result (S204) and stored. Next, the first reticle 2 is carried out, and a second reticle (second original) to be exposed by the B module (second module) is carried in and mounted onto the A module (S205), and a calibration measurement is performed similar to the first reticle 2 (S206). A correction value (B (A, Y) of an alignment error is calculated from the obtained measurement result (S207) and stored. Then, a difference value D between A(X, Y) (first correction value) and B(X, Y) (second correction value) is calculated (S208).

The correction values A(X, Y) and B(X, Y) contain an aberration of the projection optical system 3 in the A module, a shape change of the reticle 2 due to deformations, and an error of the reticle stage (although these are TISs), and a patterning error of each reticle 2. Since the same A module is used for the first and second reticles 2, the difference value D corresponds to a difference of a patterning error of the first and second reticles 2. Thus, the controller 14 can obtain the TIS in FIG. 14, and a difference of a patterning error of each reticle 2 in FIG. 15. Thereby, when one module is used to calculate a correction value of an alignment error, high overlay accuracy and high focusing accuracy can be maintained through a correction with the difference value D even when the other module is not used to obtain the correction value.

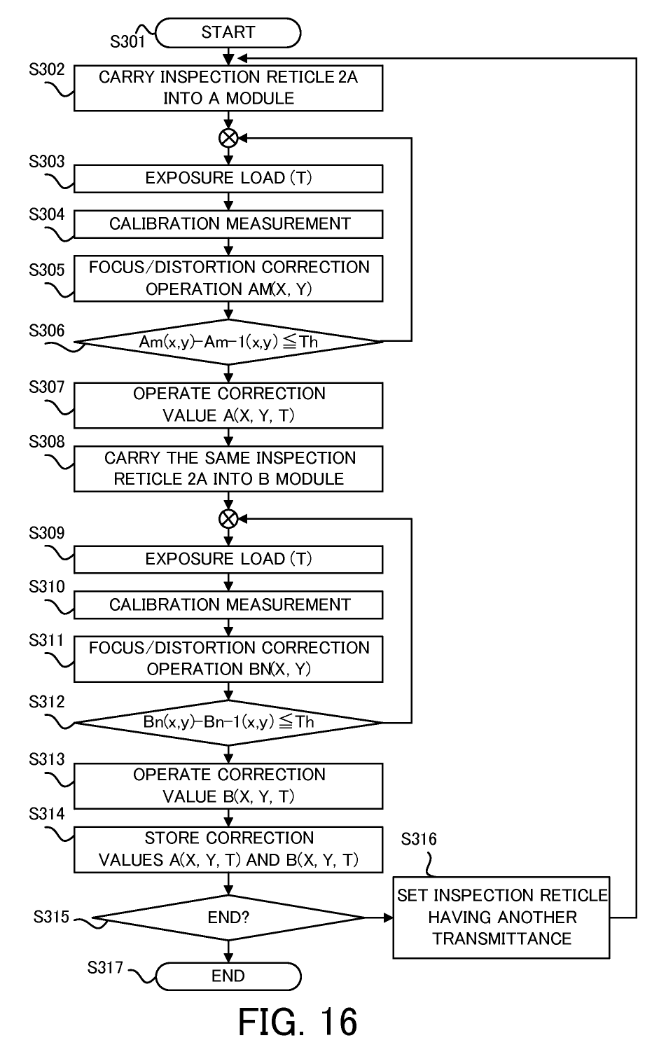

Referring now to FIG. 16, a description will be given of a method for measuring and correcting a shape change caused by the exposure light. A thermal change of the reticle 2 and a thermal change of the aberration of the projection optical system 3 can be calculated by a similar measurement method when a type of reticle 2 is changed. In other words, when the reticle 2 has a high transmittance (when the reticle 2 has a wide light transmitting area), the light quantity that transmits through the reticle 2 increases, and thus a thermal aberration change of the projection optical system 3 can be conspicuously obtained. On the contrary, a thermal deformation of the reticle 2 can be obtained by reducing the transmittance of the reticle (or by reducing the light transmitting area of the reticle 2). In addition, the measurement (exposure and calculation) may use the reticle 2 which is used to expose the wafer 6 rather than the inspection reticle 2A. This description uses the inspection reticle 2A shown in FIG. 11.

When a measurement starts (S301), the inspection reticle 2A is carried in the A module (S302). A predetermined exposure load (t) is also provided to the projection optical system 3 through the inspection reticle 2A (S303). The exposure load is an optimal dose to the capability of the exposure apparatus 100, and is, for example, an exposure dose equal to the light quantity from the light source of the illumination apparatus 1 in each module. The exposure load is defined by an irradiation time period (t) of the exposure light. A calibration measurement follows after the exposure load is given (S304). A correction value Am(X, Y) of an alignment error is calculated based on the measurement value (S305). Next, a correction value Am−1(X, Y) calculated from the previous measurement value is compared with a newly calculated correction value Am(X, Y), and whether the difference value is smaller than a threshold value Th is determined (S306). There is no previous measurement in the first measurement, and the flow automatically returns to the sequence that provides the exposure load. The exposure load and the calculation of the correction value are repeated until the change of the correction value along with the exposure load becomes the threshold value (S303-S306). A correction value A(X, Y, t) is acquired when it becomes smaller than the threshold Th (S307).

Next, the reticle 2A is carried in the B module (S308) and provided with the exposure load (S309), similar to the A module, and a calibration mark measurement is performed (S310). A correction value Bn(X, Y) of an alignment error is calculated from that measurement value (S311). Next, a correction value Bn−1(X, Y) calculated from the previous measurement value is compared with a newly calculated correction value Bn(X, Y), and whether the difference value is smaller than a threshold value Th is determined (S312). There is no previous measurement in the first measurement, and the flow automatically returns to the sequence that provides the exposure load. The exposure load and the calculation of the correction value are repeated until the change of the correction value along with the exposure load becomes the threshold value (S309-S312). A correction value B(X, Y, t) is acquired when it becomes smaller than the threshold Th (S313). Finally, the correction values A(X, Y, t) and B(X, Y, t) are stored as functions of the exposure load in the exposure apparatus 100 (S314).

A correction with these correction values is made in accordance with the exposure dose (time) in exposing the actual wafer 6. Changes of both modules along with the exposure can be minimized. The inspection reticle 2A having a high transmittance can provide information of a thermal change of the projection optical system 3. The reticle having a transmittance different from and lower than that of the reticle 2A can provide information of thermal shape changes of the reticle and the reticle stage. The controller 14 separates these factors and obtains the correction values through the measurements shown in FIG. 15 using at least two reticles having different transmittances (S315, S316). The procedure ends when all measurements end (S317). The controller 14 individually controls the correction values, calculates the transmittance of the reticle 2 used for the actual exposure by using the reference mark 15, estimates the thermal changes caused by the projection optical system 3 and the reticle 2 from that transmittance, and provides corrective exposures.

As described above, a difference of a variation with time between both modules can be minimized by calculating and correcting a thermal change between both modules, and high overlay accuracy and high focusing accuracy can be maintained by reducing a difference among modules.

In operation, each module may expose an identical reticle pattern (first pattern) onto the wafer 6, and then another identical reticle pattern (second pattern) onto another layer on the wafer 6. Even when a module that exposes the first pattern and a module that exposes the second pattern are different from each other for a certain wafer 6, the imaging error is adjusted so that each module can have an approximately equal imaging error, and thus the overlay accuracy is maintained between the first pattern and the second pattern.

A device (such as a semiconductor integrated circuit device and a liquid crystal display device) can be manufactured by the step of exposing a photosensitive agent applied substrate (such as a wafer and a glass plate) using the exposure apparatus of one of the above embodiments, the step of developing the substrate, and another well-known step.

Thus, the multi-module exposure apparatus of this embodiment uses one original that is set as a reference (reference original), measures and stores an error component that is generated in each module, and exposes an actual substrate so that an error component can be corrected. Moreover, the multi-module exposure apparatus of this embodiment uses the reference original, previously calculates an error component that varies along with exposures and is generated in each module, and exposes an actual substrate so that the error component can be corrected. Moreover, the multi-module exposure apparatus of this embodiment measures errors of respective originals used to expose an actual substrate in a predetermined module, calculates the difference, and corrects the calculated error component. Thereby, errors that may occur in the modules can be made approximately equal to each other.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-111093, filed Apr. 22, 2008, which is hereby incorporated by reference herein in its entirety.

What is claimed is:

1. An exposure apparatus comprising:
a plurality of module each of which is configured to expose a pattern of an original onto a substrate using light from a light source, each module including a projection optical system configured to project the pattern of the original onto the substrate and designed to have an identical structure; and
a controller configured to control exposures of the plurality of modules using a correction value that is set for each module and configured to correct a scatter of an imaging characteristic of the pattern of the original to be exposure onto the substrate, the controller obtaining the correction value from an inspection result obtained by sequentially mounting an inspection original onto each module.

2. An exposure apparatus according to claim 1, wherein the correction value is a correction value used to correct an imaging error in an optical-axis direction of the projection optical system or in a direction perpendicular to an optical axis of the projection optical system.

3. An exposure apparatus according to claim 1, wherein the controller corrects the correction value from a relationship between the correction value and a change to an irradiation time period from the light source.

4. An exposure apparatus according to claim 1, wherein the controller obtains the correction value by providing an exposure load to the projection optical system in each module.

5. An exposure apparatus according to claim 1, wherein the controller obtains the correction value by exposing different areas of one substrate among the plurality of modules and by inspecting an exposure result using an overlay inspection apparatus.

6. An exposure apparatus according to claim 1, wherein each module includes a position detection apparatus configure to observe the original and the substrate and to detect a positional shift between the original and the substrate, and
wherein the controller obtains the correction value from a detection result of the position detection apparatus.

7. An exposure apparatus according to claim 6, wherein each inspection original has a plurality of marks arranged in a matrix shape, and
wherein the controller interpolates a shape of the inspection original corresponding to spaces among the plurality of marks.

8. An exposure apparatus comprising:
a plurality of module each of which is configured to expose a pattern of an original onto a substrate using light from a light source, each module including a projection optical system configured to project the pattern of the original onto the substrate and designed to have an identical structure, the plurality of modules including a first module to be mounted with a first original, and a second module to be mounted with a second original; and
a controller configured to control exposures of the plurality of modules using a correction value that is set for each module and configured to correct a scatter of an imaging characteristic of the pattern of the original to be exposure onto the substrate, the controller obtaining the correction value from an inspection result obtained by mounting the first original onto the first module and from an inspection result obtained by mounting the second original onto the first module.

9. An exposure apparatus according to claim 8, wherein each module further includes a position detection apparatus configure to observe the original and the substrate and to detect a positional shift between the original and the substrate, and
wherein the controller obtains the correction value by calculating a difference between a first correction value of the first module obtained from an detection result of the position detection apparatus when the first module is mounted with the first original, and a second correction value of the first module obtained from an detection result of the position detection apparatus when the first module is mounted with the second original.

10. An exposure apparatus according to claim 2, wherein the controller obtains the correction value by calculating a difference between a first correction value of the first module obtained when the substrate is exposed in the first module mounted with the first original and an overlay inspection apparatus inspects an exposure result, and a second correction value of the first module obtained when the substrate is exposed in the first module mounted with the second original and the overlay inspection apparatus inspects an exposure result.

11. A device manufacturing method comprising the steps of:
exposing a substrate using an exposure apparatus; and
developing the substrate that has been exposed,
wherein the exposure apparatus includes:
a plurality of module each of which is configured to expose a pattern of an original onto the substrate using light from a light source, each module including a projection optical system configured to project the pattern of the original onto the substrate and designed to have an identical structure; and
a controller configured to control exposures of the plurality of modules using a correction value that is set for each module and configured to correct a scatter of an imaging characteristic of the pattern of the original to be exposure onto the substrate, the controller obtaining the correction value from an inspection result obtained by sequentially mounting an inspection original onto each module.

12. A device manufacturing method comprising the steps of:
exposing a substrate using an exposure apparatus; and
developing the substrate that has been exposed,
wherein the exposure apparatus includes:
a plurality of module each of which is configured to expose a pattern of an original onto the substrate using light from a light source, each module including a projection optical system configured to project the pattern of the original onto the substrate and designed to have an identical structure, the plurality of modules including a first module to be mounted with a first original, and a second module to be mounted with a second original; and
a controller configured to control exposures of the plurality of modules using a correction value that is set for each module and configured to correct a scatter of an imaging characteristic of the pattern of the original to be exposure onto the substrate, the controller obtaining the correction value from an inspection result obtained by mounting the first original onto the first module and from an inspection result obtained by mounting the second original onto the first module.
